(19) United States
(12) Patent Application Publication
(10) Pub. No.: US 2021/0025659 A1
(43) Pub. Date: Jan. 28, 2021

(54) FLAT HEAT PIPE

(71) Applicant: Fujikura Ltd., Tokyo (JP)

(72) Inventors: Mohammad Shahed Ahamed, Tokyo (JP); Yuji Saito, Tokyo (JP); Makoto Takahashi, Tokyo (JP)

(73) Assignee: Fujikura Ltd., Tokyo (JP)

(21) Appl. No.: 16/979,637

(22) PCT Filed: Mar. 12, 2019
(86) PCT No.: PCT/JP2019/010040

§ 371 Date: Sep. 10, 2020

(30) Foreign Application Priority Data
Mar. 12, 2018 (JP) 2018-044627

(51) Int. Cl. F28D 15/04; F28D 15/02

(52) U.S. Cl. CPC F28D 15/046; H05K 7/20336; F28D 15/0233

(57) ABSTRACT

A flat heat pipe includes: a container that encloses a working fluid; and a wick structure disposed inside the container. The wick structure includes copper alloy fibers, and L≤140 [μm] and L/D≥8.75 are satisfied where L is a distance between an upper wall and a lower wall of the container and D is a diameter of each of the copper alloy fibers.

### CROSS-REFERENCE TO RELATED APPLICATIONS

This is a U.S. National Stage application of International Application No. PCT/JP2019/010040 filed Mar. 12, 2019, which claims priority to Japanese Patent Application No. 2018-044627 filed Mar. 12, 2018. These references are incorporated herein by reference in their entirety.

### TECHNICAL FIELD

The present invention relates to a flat heat pipe.

### BACKGROUND

Conventionally, a flat heat pipe as shown in Patent Document 1 is known. The heat pipe is includes a container in which working fluid is enclosed and a wick structure arranged in the container. Using the phase change of the working fluid, heat can be repeatedly transported from an evaporator to a condenser.

In addition, in Patent Document 1, a wick structure is formed by bundling thin metal wires (fibers) such as copper wires.

### PATENT DOCUMENT

[Patent Document 1] Japanese Unexamined Patent Application, First Publication No. 2012-229879

The wire diameter of the copper fiber generally used is approximately 25 μm at the smallest. This is because when the wire diameter of the copper fiber is smaller than 25 μm, the tensile strength becomes insufficient and it becomes difficult to manufacture or use the copper fiber itself.

On the other hand, in recent years, it has been required to make the thickness of the heat pipe extremely small (for example, 300 μm or less). When the thickness of the heat pipe is extremely small, the thickness of the internal space of the container becomes also extremely small (for example, 140 μm or less).

Here, when the same copper fiber as the conventional one is used as the wick structure and the thickness of the internal space of the container is reduced, the number of copper fibers that can be arranged in the internal space decreases. When the number of copper fibers is small, the gaps between the copper fibers are likely not to be uniform. As a result, the capillary force acting on the liquid-phase working fluid varies, and the heat transport performance becomes unstable.

### SUMMARY

One or more embodiments of the present invention provide a flat heat pipe having stable heat transport performance even when the thickness is extremely small.

A flat heat pipe according to one or more embodiments of the present invention includes a long-sized container in which a working fluid is enclosed; and a wick structure arranged inside the container, where the wick structure is formed by a plurality of fibers made of copper alloy (copper alloy fibers), and L≤140 [μm] and L/D≥8.75, when L is a distance between an upper wall and a lower wall of the container and D is a diameter of the fiber.

According to one or more embodiments described above, a copper alloy fiber is used as the wick structure. The copper alloy fiber can reduce the wire diameter while maintaining the tensile strength, as compared with the conventional copper fiber. Therefore, more fibers can be arranged in the container, and the gaps between the fibers can be made uniform even when the thickness of the internal space is extremely small. In addition, by making the gaps between the fibers uniform, variations in the capillary force acting on the liquid-phase working fluid are reduced, and the heat transport performance is stabilized.

Furthermore, since L/D≥8.75, at least 5 or more fibers are secured in the thickness direction of the container. Therefore, even with an extremely thin flat heat pipe with L≤140 [μm], it is possible to avoid that the gaps between the fibers become non-uniform due to too few fibers. As a result, the heat transport performance can be stabilized more reliably.

A flat heat pipe according to one or more embodiments of the present invention includes a long-sized container in which a working fluid is enclosed; and a wick structure arranged inside the container, where the wick structure is formed by a plurality of fibers made of copper alloy, a distance between an upper wall and a lower wall of the container is 140 μm or less, and a density of the fibers in the wick structure is 1600 [pieces/mm²] or more.

According to one or more embodiments described above, the density of the fibers in the wick structure is 1600 [pieces/mm²] or more. As a result, even in a case of an extremely thin flat heat pipe in which the distance between an upper wall and a lower wall of the container is 140 μm or less, it can be avoided that the number of fibers is too small and thus, the gaps between the fibers become non-uniform. Therefore, the heat transport performance can be stabilized more reliably.

Here, a diameter of the fibers may be less than 25 μm.

In such a case, for example, even when the thickness of the internal space of the container is 140 μm or less, a sufficient number of fibers can be accommodated in the container to make the gaps between the fibers uniform.

In addition, a diameter of the fibers may be less than 16 μm and a tensile strength of the fibers may be 650 MPa or more.

In such a case, the number of fibers that can be accommodated in the container can be increased by setting the diameter of the fibers to 16 μm or less.

In addition, when the tensile strength of the fiber is 650 MPa or more, the fiber is prevented from being abruptly broken.

The wick structure may have a structure in which the plurality of fibers are filled between the upper wall and the lower wall of the container, and a vapor flow path may be formed between the side wall of the container and the wick structure.

In such a case, the fibers are filled between the upper wall and the lower wall of the container, so that the gap between the fibers becomes more uniform.

Moreover, the working fluid in the vapor phase can be reliably moved through the vapor flow path.

The wick structure may have a structure in which a plurality of wick bodies formed by braiding the plurality of fibers into a tubular shape are annularly arranged in a cross-sectional view orthogonal to a longitudinal direction of the container.

In such a case, an inner portion of the annular wick structure can function as a flow path (vapor flow path) of the vapor-phase working fluid or a flow path (liquid flow path) of the liquid-phase working fluid. In addition, since each wick body forming the wick structure is formed in a tubular shape, the inner portion of the wick bodies can function as a liquid flow path. With such configuration, the flow resistance when recirculating the liquid-phase working fluid can be reduced smaller than that of the conventional heat pipe, and the heat transport performance of the heat pipe can be improved.

In addition, each wick body is formed by braiding fibers. Therefore, as compared with the case where the wick body is formed by a twisted wire, for example, it is possible to reduce variation in the flow resistance of the working fluid in the liquid phase flowing in the wick body due to the variation in the twisting degree. As a result, it is possible to reduce the manufacturing variation in the heat transport performance of the heat pipe due to the variation in the flow resistance. Furthermore, since the braided wire can have a higher permeability and a higher porosity than a stranded wire, sintered copper powder, or the like, the flow resistance of the working fluid in the liquid phase can be further reduced.

The plurality of fibers may be formed of a copper alloy including silver.

In such a case, by using a copper alloy including silver, it is possible to enhance the tensile strength of the fiber while taking advantage of the heat conduction characteristics of copper. Therefore, the wire diameter of the fiber can be further reduced.

The plurality of fibers may be formed of a copper alloy including 3 wt % or more of silver.

In such a case, for example, the tensile strength can be 650 MPa or more while the fiber diameter is 16 μm or less.

According to embodiments of the present invention described above, it is possible to provide a flat heat pipe with stable heat transport performance even when the thickness is extremely small.

### BRIEF DESCRIPTION OF THE DRAWINGS

FIG. 1 is a cross-sectional view of the flat heat pipe according to the first embodiment.

FIG. 2 is a cross-sectional view of the flat heat pipe according to the second embodiment.

### DETAILED DESCRIPTION

### First Embodiment

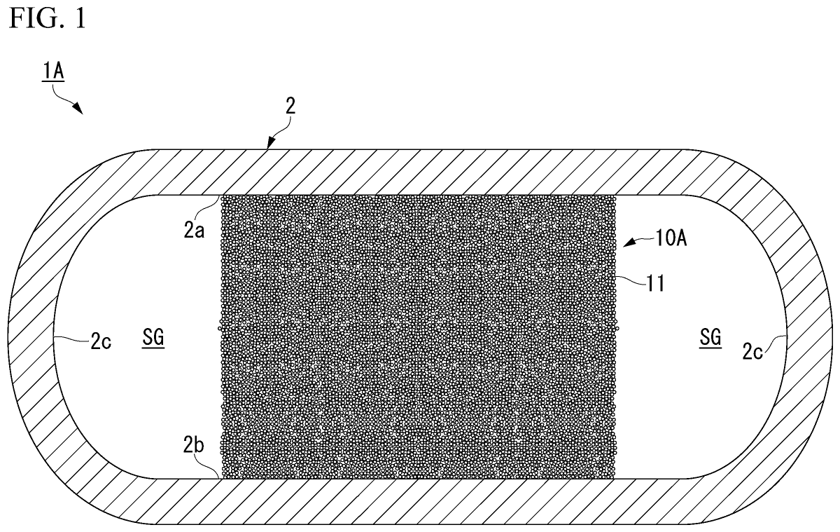

The configuration of a flat heat pipe according to the first embodiment will be described below with reference to FIG. 1.

As shown in FIG. 1, the flat heat pipe 1A according to the present embodiment includes a container 2 in which a working fluid is enclosed, and a wick structure 10A arranged in the container 2. The wick structure 10A is impregnated with liquid-phase working fluid. As the working fluid, well-known fluid such as water, alcohols, and ammonia water can be used.

### (Definition of Direction)

The container 2 is formed in a long shape. Hereinafter, the longitudinal direction of the container 2 is simply referred to as the longitudinal direction, and the cross section orthogonal to the longitudinal direction is simply referred to as the horizontal cross section.

The thickness direction of the container 2 is simply referred to as the thickness direction, and the width direction of the container 2 is simply referred to as the width direction.

The container 2 is a flat container that is longer in the width direction than in the thickness direction in a cross-sectional view. The container 2 has an upper wall 2a, a lower wall 2b, and a side wall 2c. The upper wall 2a and the lower wall 2b are substantially parallel to each other in a cross-sectional view. The wick structure 10A is arranged at the center of the container 2 in the width direction. Thereby, a space (steam flow path SG) is provided between the wick structure 10A and the side wall 2c of the container 2. The vapor flow paths SG are provided at two positions so as to sandwich the wick structure 10A in the width direction of the container 2. These vapor flow paths SG function as flow paths for a vapor-phase working fluid.

The wick structure 10A extends in the longitudinal direction so as to connect between the evaporator and the condenser (not shown) in the flat heat pipe 1A. The wick structure 10A has a structure in which a plurality of fibers 11 are filled between the upper wall 2a and the lower wall 2b of the container 2. The plurality of fibers 11 may be twisted with each other or may be simply bundled.

Here, the flat heat pipe 1A of the present embodiment has an extremely thin shape with a thickness of, for example, approximately 300 μm. Therefore, when the wick structure 10A is formed by a conventional copper fiber having a wire diameter of 25 μm or more with a space between the upper wall 2a and the lower wall 2b being, for example, 140 μm or less, the number of copper fibers in the thickness direction is insufficient. As a result, the gaps between the copper fibers become non-uniform. That is, the wire diameter (diameter) of the fibers forming the wick structure 10A may be less than 25 μm.

Therefore, the fiber 11 of the present embodiment is formed of a copper alloy including silver. By using the copper alloy including silver, the tensile strength of the fiber 11 can be increased while taking advantage of the heat conduction characteristics of copper. When the tensile strength is high, the strength can be maintained even if the fiber diameter of the fiber 11 is reduced, so that the fiber 11 having an extremely small wire diameter can be used. The smaller the wire diameter is, the larger the number of fibers 11 accommodated in the container 2 and the more uniform the gaps between the fibers 11 becomes.

In one example, when a copper alloy including 3 wt % or more of silver was used, the tensile strength could be 650 MPa or more while the fiber diameter of the fiber 11 was 16 μm or less.

Next, the operation of the flat heat pipe 1A configured as described above will be described.

Capillary force acts on the liquid-phase working fluid impregnating the wick structure 10A. During operation of the flat heat pipe 1A, the working fluid in the liquid phase is vaporized by the external heat in the evaporator to become a gas, and the gas flows through the vapor passage SG to move to the condenser. In the condenser, the vapor-phase working fluid radiates heat to be condensed, and the liquid-phase working fluid impregnates the wick structure 10A. Then, the capillary force of the wick structure 10A causes the working fluid in the liquid phase to flow back from the condenser to the evaporator. The liquid-phase working fluid that has reached the evaporator evaporates again. In this manner, the flat heat pipe 1A can repeatedly transport heat from the evaporator to the condenser.

In the present embodiment, the fiber 11 of a copper alloy is used as the wick structure 10A. The fiber 11 of a copper alloy can reduce the wire diameter while maintaining the strength, as compared with a conventional copper fiber (for example, a wire diameter of 30 μm and a tensile strength of 700 MPa). Therefore, it is possible to arrange a larger number of fibers 11 in the container 2, and even if the distance between the upper wall 2a and the lower wall 2b is extremely small, it is possible to make the gaps between the fibers 11 uniform. By making the gaps between the fibers 11 uniform, variations in the capillary force acting on the liquid-phase working fluid are reduced, and the heat transport performance of the flat heat pipe 1A is stabilized.

Further, by using a copper alloy including silver as the material of the fiber 11, the tensile strength of the fiber 11 can be increased while utilizing the heat conduction characteristics of copper. Therefore, the diameter of the fiber 11 can be made smaller, for example, less than 25 μm.

Furthermore, for example, when the fiber 11 is formed of a copper alloy including 3 wt % or more of silver, the tensile strength can be 650 MPa or more while the fiber 11 has a wire diameter (diameter) of 16 μm or less.

Here, the result of examining the relationship between the number of fibers 11 in the container 2 and the heat transport performance will be described based on Table 1 below.

TABLE 1

| | WIRE | | | | | | | ΔP_{C} − | |
|---|---|---|---|---|---|---|---|---|---|
| | DIAMETER | DISTANCE | | | Δ P_{C} | Δ P_{L} | Δ P_{V} | (ΔP_{L} + | |
| | D (μm) | L (μm) | L/D | MATERIAL | (Pa) | (Pa) | (Pa) | P_{V}) | DETERMINATION |
| COMPARATIVE | 25 | 140 | 5.6 | COPPER | 4030 | 581 | 4205 | −756 | NG |
| EXAMPLE | | | | | | | | | |
| EXAMPLE | 16 | 140 | 8.75 | COPPER & | 5580 | 605 | 4205 | 770 | OK |
| | | | | SILVER | | | | | |

As shown in Table 1, here, the heat transport performances of the two flat heat pipes of the comparative example and the example were compared. The wire diameter D of the fiber 11 of the comparative example was 25 μm, and the material was copper. The wire diameter D of the fiber 11 of the example was 16 μm, and the material was a copper alloy including silver. “Space L” in Table 1 indicates the space between the upper wall 2a and the lower wall 2b of the container 2. In both the example and the comparative example, L=140 μm. In the comparative example, L/D=5.6, and in the example, L/D=8.75.

ΔPC in Table 1 indicates the capillary force generated by the fiber 11. ΔP_{L} in Table 1 indicates the pressure loss of the working fluid in the liquid phase. ΔP_{V} in Table 1 indicates the pressure loss of the working fluid in the gas phase. The operating condition of the heat pipe is represented by the following conditional expression (1) or (2).

ΔP_{C}≥ΔP_{L}+ΔP_{V} (1)

ΔP_{C}−(ΔP_{L}+ΔP_{V})≥0 (2)

That is, if the left side of the expression (2) is a positive value, the conditions (1) and (2) are satisfied, and the heat pipe operates normally.

Here, as shown in Table 1, in the heat pipe of the comparative example, the left side of the expression (2) has a negative value. Therefore, it is considered that the heat pipe of the comparative example does not operate normally. On the other hand, in the heat pipe of the embodiment, the left side of expression (2) has a positive value. Therefore, the heat pipe of the embodiment operates normally.

Comparing the conditions of the comparative example and the example, the wire diameter D of the fiber 11 is different, and therefore the values of ΔP_{C} and ΔP_{L} are also different. More specifically, since the wire diameter D of the example is smaller than that of the comparative example, the gap between the fibers 11 is small and the capillary force (ΔP_{C}) is large. As a result, the value on the left side of the expression (2) can be increased to a positive value. Since the gap between the fibers 11 is smaller in the example than in the comparative example, the pressure loss (ΔP_{L}) of the working fluid in the liquid phase is also larger. Although the increase of ΔP_{L} decreases the left side of the expression (2), the increase of ΔP_{C} exceeds the decrease, and therefore the embodiment satisfies the conditional expression (2).

As described above, it was confirmed that the heat transfer performance of the flat heat pipe can be secured by setting the wire diameter D to be less than 25 μm, or to be 16 μm or less.

In addition, the inventors of the present application conducted further studies and found that the number of fibers 11 accommodated in the container 2 is important for ensuring the heat transport performance of the flat heat pipe.

More specifically, the relationship of L/D≥8.75 may be satisfied when the distance between the upper wall 2a and the lower wall 2b of the container 2 is L and the diameter of the fiber 11 is D. As a result, since the capillary force generated by the fiber is larger than the sum of the pressure loss of the liquid-phase working fluid and the pressure loss of the gas-phase working fluid, the liquid-phase working fluid recirculates from the condenser to the evaporator. Therefore, even with an extremely thin flat heat pipe with L≤140 [μm], it is possible to avoid that the gap between the fibers becomes non-uniform due to the too small number of fibers 11. As a result, the heat transport performance can be stabilized more reliably. As shown in Table 1, L/D=8.75 in the example, which allowed ΔP_{C}−(ΔP_{L}+ΔP_{V})=770 (positive value). From the above, the effect of setting L/D≥8.75 was confirmed.

The density of the fibers 11 in the wick structure 10A may be 1600 [lines/mm²] or more. The “density of the fibers 11” in the present embodiment is a value obtained by dividing the number of fibers 11 in the container 2 by the area occupied by the wick structure 10A in the cross-section (the area of the central rectangular region in FIG. 1). Even with an extremely thin flat heat pipe such that the distance between the upper wall 2a and the lower wall 2b is 140 μm or less, by setting the density of the fibers 11 to 1600 [lines/mm²] or more, it is possible to prevent the gap between the fibers 11 from becoming non-uniform due to the number of fibers 11 being too small. Therefore, the heat transport performance can be stabilized more reliably.

### Second Embodiment

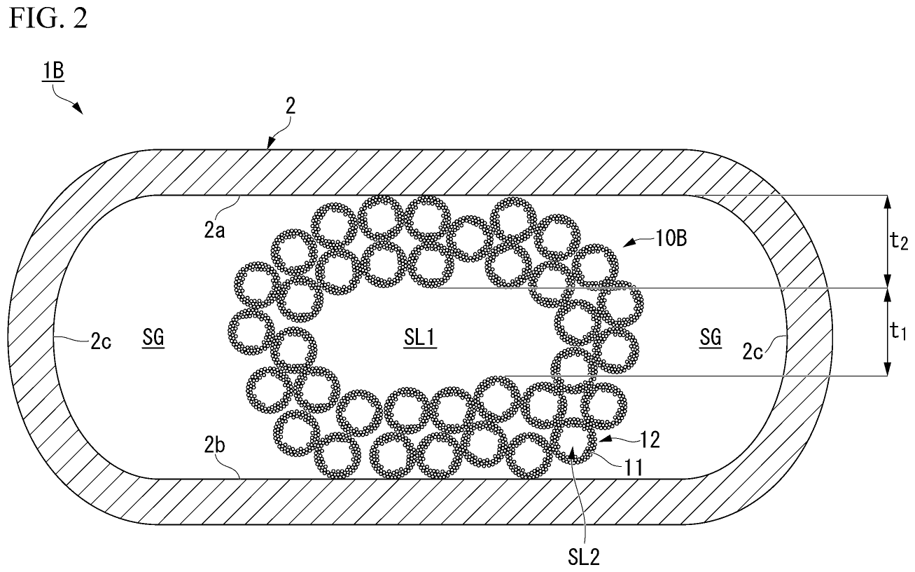

Next, a second embodiment according to the present invention will be described; however, the basic configuration is the same as that of the first embodiment. Therefore, the same reference numerals are given to the same configurations, the description thereof is omitted, and only different portions will be described. As shown in FIG. 2, the flat heat pipe 1B of the present embodiment differs from the first embodiment in the configuration of the wick structure.

As shown in FIG. 2, the wick structure 10B of the present embodiment has a structure in which a plurality of wick bodies 12 are arranged in a substantially elliptical annular shape in a cross-sectional view. As a result, a space (liquid flow path SL1) extending in the longitudinal direction is formed inside the wick structure 10B. The wick structure 10B is in contact with the upper wall 2a and the lower wall 2b of the container 2.

Each wick body 12 is formed in a tubular shape by a braided wire formed by braiding a plurality of fibers 11 made of a copper alloy. As a result, a space (liquid flow path SL2) extending in the longitudinal direction is formed inside each wick body 12. The gap between the fibers 11 is impregnated with the liquid-phase working fluid, and the size of this gap is set so that the capillary force acts on the liquid-phase working fluid. That is, the gap between the fibers 11 functions as a flow path for the liquid-phase working fluid.

The thickness t1 of the liquid flow path SL1 in the thickness direction of the container 2 may be smaller than the thickness t2 from the inner peripheral surface to the outer peripheral surface of the wick structure 10B. When the thickness t1 is not constant in the width direction as shown in FIG. 2, the average value in the width direction is defined as the thickness t1. Similarly, when the thickness t2 is not constant in the width direction, or when the thickness t2 is different between the upper side and the lower side, the average value of the whole is defined as the thickness t2.

Next, with respect to the operation of the flat heat pipe 1B configured as described above, differences from the first embodiment will be described.

Since the wick structure 10B of the present embodiment is formed in an annular shape in a cross-sectional view, the space inside the wick structure 10B can function as the first liquid flow path SL1 through which the liquid-phase working fluid flows. In addition, since each wick body 12 forming the wick structure 10B is formed in a tubular shape, the space inside these wick bodies 12 can function as the second liquid flow path SL2 through which the working fluid in the liquid phase flows. With such configuration, the flow resistance at the time of recirculating the liquid-phase working fluid can be reduced smaller than that of the conventional heat pipe, and the heat transport performance can be improved.

Furthermore, even if the cross-sectional area of the wick structure 10B is small, the liquid-phase working fluid smoothly flows in the wick structure 10B, so that the area occupied by the wick structure 10B in the container 2 is reduced and the steam flow path SG is reduced. It is possible to increase the flow passage cross-sectional area. This makes it possible to reduce the flow resistance of the vapor-phase working fluid flowing through the SG in the vapor passage to be small.

Since the wick body 12 is formed of a braided wire, for example, compared with the case where the wick body 12 is formed of a twisted wire, the flow of the working fluid in the liquid phase flowing in the wick body 12 due to the variation in the twisting condition. It is possible to reduce variations in resistance. As a result, it is possible to reduce the manufacturing variation in the heat transport performance of the flat heat pipe 1B due to the variation in the flow resistance. Furthermore, since the braided wire can have a higher permeability and a higher porosity than a stranded wire or sintered copper powder, the flow resistance of the working fluid in the liquid phase can be further reduced.

Further, as in the first embodiment, the fiber 11 may be made of a copper alloy including, for example, 3 wt % or more of silver. As a result, the wire diameter of the fiber 11 can be reduced while increasing the tensile strength of the fiber 11.

The thickness t1 of the liquid flow path SL1 in the thickness direction of the container 2 may be smaller than the thickness t2 from the inner peripheral surface to the outer peripheral surface of the wick structure 10B. As described above, by reducing the thickness t1 of the liquid flow path SL1, the capillary radius of the working fluid in the liquid phase in the liquid flow path SL1 becomes smaller, and the working fluid in the liquid phase can be more reliably held in the liquid flow path SL1. As a result, the liquid-phase working fluid condensed in the condenser moves smoothly in the liquid flow path SL1 toward the evaporator, so that the heat transport efficiency is further improved.

Also in the case of the present embodiment, L/D≥8.75 may be satisfied as in the first embodiment. The density of the fibers 11 in the wick structure 10B may be 1600 [lines/mm²] or more. The “density of fibers 11” in the present embodiment is a value obtained by dividing the number of fibers 11 in the container 2 by the area occupied by the wick structure 10B in the cross section. The area occupied by the wick structure 10B does not include the space inside the wick body 12 (the liquid flow path SL2 in FIG. 2) and the gap between the wick bodies 12. In other words, the “density of the fibers 11” is a value obtained by dividing the number of fibers 11 contained in the wick body 12 by the area occupied by the annular wall of the wick body 12.

The technical scope of the present invention is not limited to the above-mentioned embodiments, and various modifications can be made without departing from the spirit of the present invention.

For example, in FIG. 1, the wick structure 10A may be divided in the width direction. In this case, the gap formed by being divided can be used as a flow path of a working fluid in a vapor phase or a liquid phase. Further, in FIG. 2, the wick body 12 may not be annularly arranged, and the wick body 12 may be filled between the upper wall 2a and the lower wall 2b.

In addition, it is possible to appropriately replace the constituent elements in the above-described embodiments with known constituent elements without departing from the spirit of the present invention, and the above-described embodiments and modified examples may be appropriately combined.

### DESCRIPTION OF THE REFERENCE SYMBOLS

1A, 1B: Flat heat pipe, 2: Container, 2a: Upper wall, 2b: Lower wall, 2c: Side wall, 10A, 10B: Wick structure, 11: Fiber, 12: Wick body, G: Steam flow path

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

1. A flat heat pipe comprising:
a container that encloses a working fluid; and
a wick structure disposed inside the container, wherein
the wick structure comprises copper alloy fibers, and
L≤140 [μm] and L/D≥8.75 are satisfied where L is a distance between an upper wall and a lower wall of the container and D is a diameter of each of the copper alloy fibers.

2. A flat heat pipe comprising:
a container that encloses a working fluid; and
a wick structure disposed inside the container, wherein
the wick structure comprises copper alloy fibers,
a distance between an upper wall and a lower wall of the container is 140 μm or less, and
a density of the copper alloy fibers in the wick structure is 1600 [pieces/mm²] or more.

3. The flat heat pipe according to claim 1, wherein the diameter of each of the copper alloy fibers is less than 25 μm.

4. The flat heat pipe according to claim 3, wherein
the diameter of each of the copper alloy fibers is less than 16 μm, and
a tensile strength of each of the copper alloy fibers is 650 MPa or more.

5. The flat heat pipe according to claim 1, wherein
the copper alloy fibers of the wick structure are filled between the upper wall and the lower wall of the container, and
the container comprises a vapor flow path between a side wall of the container and the wick structure.

6. The flat heat pipe according to claim 1, wherein
the wick structure further comprises wick bodies annularly disposed in a cross-sectional view orthogonal to a longitudinal direction of the container, wherein
the wick bodies are the copper alloy fibers braided into a tubular shape.

7. The flat heat pipe according to claim 1, wherein a copper alloy of the copper alloy fibers including comprises silver.

8. The flat heat pipe according to claim 7, wherein the the copper alloy comprises 3 wt % or more of silver.
